(19) United States
(12) Patent Application Publication
(10) Pub. No.: US 2007/0026148 A1
(43) Pub. Date: Feb. 1, 2007

(54) Vapor phase deposition apparatus and vapor phase deposition method

(75) Inventors: Hideki Arai, Shizuoka (JP); Hironobu Hirata, Shizuoka (JP); Yoshikazu Moriyama, Shizuoka (JP); Shinichi Mitani, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: NuFlare Technology, Inc.

(21) Appl. No.: 11/494,674

(22) Filed: Jul. 28, 2006

(30) Foreign Application Priority Data
Jul. 29, 2005 (JP) 2005-219943
Dec. 21, 2005 (JP) 2005-367484
Jan. 13, 2006 (JP) 2006-005523

(51) Int. Cl. C23C 16/00

(52) U.S. Cl. 427/248.1; 118/728; 118/730

(57) ABSTRACT

A vapor phase deposition apparatus includes a chamber, a support table which is accommodated in the chamber and supports a substrate in the chamber, a first passage which supplies a gas to form a film and is connected to the chamber, and a second passage which discharges the gas and is connected to the chamber, the support table is provided with a plurality of first projecting portions to constrain a substantially horizontal movement in the same direction as a substrate surface with respect to the substrate, and the substrate is supported on a surface to come in contact with a back face of the substrate.

### CROSS-REFERENCE TO RELATED APPLICATION

This application is based upon and claims the benefit of priority from prior Japanese Patent Application No. JP 2005-219943 filed on Jul. 29, 2005 in Japan, prior Japanese Patent Application No. JP 2005-367484 filed on Dec. 21, 2005 in Japan, and prior Japanese Patent Application No. JP 2006-005523 filed on Jan. 13, 2006 in Japan, the entire contents of which are incorporated herein by reference.

### BACKGROUND OF THE INVENTION

1. Field of the Invention

The present invention relates to a vapor phase deposition apparatus and method. And for example, the present invention relates to a shape of a support member (a support table) for supporting a substrate such as a silicon wafer in an epitaxial growth apparatus.

2. Related Art

In the manufacture of a semiconductor apparatus such as a very high speed bipolar or a very high speed CMOS, an epitaxial growth technique for a single crystal having its impurity concentration and film thickness controlled is indispensable for enhancing the performance of the semiconductor devices.

For an epitaxial growth for causing a single crystal thin film to be vapor phase grown over a semiconductor substrate such as a silicon wafer, an atmospheric chemical vapor deposition method is generally used. According to circumstances, a low pressure chemical vapor deposition (LP-CVD) method is used. A semiconductor substrate such as a silicon wafer is disposed in a reactor and is heated and rotated in a state in which the inside of the reactor is held in an atmospheric pressure (0.1 MPa (760 Torr)) or a vacuum having a predetermined degree of vacuum, and at the same time, a raw gas containing a silicon source and a dopant such as a boron compound, an arsenic compound or a phosphorus compound is supplied. Then, the thermal decomposition or hydrogen reduction of the raw gas is carried out over a surface of the heated semiconductor substrate, and a silicon epitaxial film doped with boron (B), phosphorus (P) or arsenic (As) is grown (see Published Unexamined Japanese Patent Application No. 09-194296 (JP-A-09-194296), for example).

Moreover, the epitaxial growth technique is also used for manufacturing a power semiconductor, such as an IGBT (insulated gate bipolar transistor). In the power semiconductor such as the IGBT, for example, a silicon epitaxial film having a thickness of several tens μm or more is required.

FIG. 24 is a top view showing an example of a state in which a silicon wafer is supported on a holder.

FIG. 25 is a sectional view showing a section of the state in which the silicon wafer is supported on the holder illustrated in FIG. 24.

A counterbore or depressed portion having a slightly larger diameter than the diameter of a silicon wafer 200 is formed on a holder 210 (which is also referred to as a susceptor) to be a support member for the silicon wafer 200. The silicon wafer 200 is mounted to be accommodated in the counterbore. In such a state, the holder 210 is rotated to rotate the silicon wafer 200 so that a silicon epitaxial film is grown by the thermal decomposition or hydrogen reduction of the raw gas thus supplied.

When the silicon wafer 200 is mounted on the holder 210 provided with the counterbore having a slightly larger diameter than the diameter of the silicon wafer 200 and they are rotated, the silicon wafer 200 is moved in a horizontal direction substantially parallel to a wafer plane by a centrifugal force thereof and approaches a part of a side surface of the counterbore. In the case in which a silicon epitaxial film (N based film) having a thickness of several tens μm or more, for example, 50 μm or more which is required for manufacturing the power semiconductor such as an insulated gate bipolar transistor (IGBT) is to be formed, there is a problem in that the following phenomenon is generated in the holder 210. More specifically, the silicon epitaxial film grown on the side surface portion of the silicon wafer 200 is stuck (bonded) in contact with a film deposited on the side surface of the counterbore of the holder 210 so that the silicon wafer 200 is stuck to the holder 210 when the silicon wafer 200 is to be delivered. In the worst case, there is a problem in that the silicon wafer 200 is broken when the silicon wafer 200 is taken out for delivery.

### BRIEF SUMMARY OF THE INVENTION

Embodiments consistent with the present invention, overcome one or more of the above-described problems and disadvantages of the related art.

In accordance with embodiments consistent with the present invention, there is provided a vapor phase deposition apparatus comprising: a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber, wherein the support table includes a plurality of projecting portions to constrain substantially horizontal movement of the substrate within an area surrounded by the plurality of projecting portions, and a bottom face of the support table for supporting a back face of the substrate.

Also, in accordance with embodiments consistent with the present invention, there is provided a vapor phase deposition apparatus comprising: a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber, wherein the support table is provided with a ring adapted to constrain substantially horizontal movement of the substrate within an area surrounded by the ring.

Further, in accordance with embodiments consistent with the present invention, there is provided a vapor phase deposition apparatus comprising: a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber, wherein the support table includes a first surface adapted to constrain substantially horizontal movement of the substrate, the first surface being formed to be round and projecting toward the substrate, and a second surface of the support table for supporting a back face of the substrate.

Additionally, in accordance with embodiments consistent with the present invention, there is provided a vapor phase deposition apparatus comprising: a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber, wherein the support table includes a plurality of projecting portions each including a top face, selected ones of the top faces of the projecting portions for contacting and supporting the substrate.

Also in accordance with embodiments consistent with the present invention, there is provided a vapor phase deposition apparatus comprising: a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber, wherein the support table includes a plurality of first projecting portions to constrain substantially horizontal movement of the substrate within an area surrounded by the first projecting portions, and a plurality of second projecting portions having top faces adapted to support the substrate thereon.

Further in accordance with embodiments consistent with the present invention, there is provided a vapor phase deposition method using a vapor phase deposition apparatus in which a substrate mounted on a support table is accommodated in a chamber, and a first passage which supplies a gas to form a film and a second passage which discharges the gas are connected to the chamber, the method comprising: rotating the support table including a plurality of projecting portions and constraining substantially horizontal movement of the substrate within an area surrounded by the plurality of projecting portions, while supporting a back face of the substrate with a bottom face portion of the support table; and supplying the gas which forms a film from the first passage to carry out an epitaxial growth.

Additionally, in accordance with embodiments consistent with the present invention, there is provided a vapor phase deposition method using a vapor phase deposition apparatus in which a substrate mounted on a support table is accommodated in a chamber, and a first passage which supplies a gas to form a film and a second passage which discharges the gas are connected to the chamber, the method comprising: rotating the support table including a ring and constraining substantially horizontal movement of the substrate within an area surrounded by the ring, while supporting a back face of the substrate with a bottom face portion of the support table; and supplying the gas which forms a film from the first passage to carry out an epitaxial growth.

Also in accordance with embodiments consistent with the present invention, there is provided a vapor phase deposition method using a vapor phase deposition apparatus in which a substrate mounted on a support table is accommodated in a chamber, and a first passage which supplies a gas to form a film and a second passage which discharges the gas are connected to the chamber, the method comprising: rotating the support table including a first surface, which is formed to be round and projecting toward the substrate and constraining substantially horizontal movement of the substrate, while supporting a back face of the substrate with a second surface of the support table; and supplying the gas which forms a film from the first passage to carry out an epitaxial growth.

Further in accordance with embodiments consistent with the present invention, there is provided a vapor phase deposition method using a vapor phase deposition apparatus in which a substrate mounted on a support table is accommodated in a chamber, and a first passage which supplies a gas to form a film and a second passage which discharges the gas are connected to the chamber, the method comprising: rotating the support table including a plurality of first projecting portions and constraining substantially horizontal movement of the substrate within an area surrounded by the plurality of first projecting portions, and a plurality of second projecting portions adapted to come in contact with the substrate, while supporting the substrate on top faces of the second projecting portions; and supplying the gas which forms a film from the first passage to carry out an epitaxial growth.

### BRIEF DESCRIPTION OF THE DRAWINGS

FIG. 1 is a conceptual view showing a structure of an epitaxial deposition apparatus according to a first embodiment,

FIG. 2 is a view showing an example of an appearance of an epitaxial deposition apparatus system,

FIG. 3 is a view showing an example of a unit structure of the epitaxial deposition apparatus system,

FIG. 4 is a top view showing an example of a state in which a silicon wafer is supported on a holder,

FIG. 5 is a sectional view showing a section of the state in which the silicon wafer is supported on the holder illustrated in FIG. 4,

FIG. 6 is a top view showing another example of the state in which the silicon wafer is supported on the holder,

FIG. 7 is a sectional view showing a section of the state in which the silicon wafer is supported on the holder illustrated in FIG. 6,

FIG. 8 is a top view showing yet another example of the state in which the silicon wafer is supported on the holder,

FIG. 9 is a sectional view showing a section of the state in which the silicon wafer is supported on the holder illustrated in FIG. 8,

FIG. 10 is a top view showing a further example of a state in which the silicon wafer is supported on the holder,

FIG. 11 is a sectional view showing a section of the state in which the silicon wafer is supported on the holder illustrated in FIG. 10,

FIG. 12 is a sectional view showing an outer peripheral portion of the silicon wafer and a projecting portion,

FIG. 13 is a top view showing a further example of the state in which the silicon wafer is supported on the holder,

FIG. 14 is a sectional view showing a section of the state in which the silicon wafer is supported on the holder illustrated in FIG. 13,

FIG. 15 is a sectional view showing the outer peripheral portion of the silicon wafer and the projecting portion,

FIG. 16 is a top view showing a further example of the state in which the silicon wafer is supported on the holder,

FIG. 17 is a sectional view showing a state of the state in which the silicon wafer is supported on the holder illustrated in FIG. 16,

FIG. 18 is a sectional view showing the outer peripheral portion of the silicon wafer and the projecting portion,

FIG. 19 is a view for explaining a state brought after the formation of a film in the case in which a holder having no projecting portion formed thereon is used,

FIGS. 20A and 20B are views for explaining a state brought after the formation of a film in the case in which a holder having the projecting portion formed thereon is used according to the present embodiment,

FIG. 21 is a chart showing an example of a relationship between a thickness of a silicon epitaxial film in each holder shape and a condition of sticking to the holder,

FIG. 22 is a top view showing an example of a state in which a silicon wafer is supported on a holder according to a second embodiment,

FIG. 23 is a sectional view showing a section of the state in which the silicon wafer is supported on the holder illustrated in FIG. 22,

FIG. 24 is a top view showing an example of the state in which the silicon wafer is supported on the holder,

FIG. 25 is a sectional view showing a section of the state in which the silicon wafer is supported on the holder illustrated in FIG. 24,

FIG. 26 is a top view showing another example of the state in which the silicon wafer is supported on the holder (support table), and

FIG. 27 is a perspective view showing a second projecting portion in FIG. 26 which is enlarged.

### DETAILED DESCRIPTION OF THE INVENTION

### First Embodiment

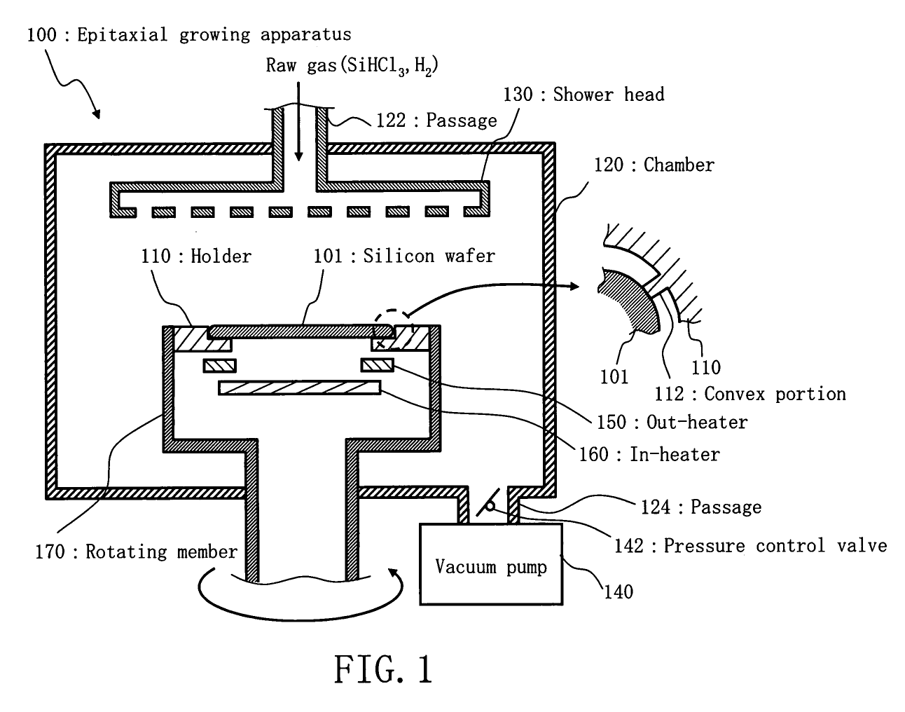

FIG. 1 is a conceptual view showing a structure of an epitaxial deposition apparatus according to a first embodiment.

In FIG. 1, an epitaxial deposition apparatus 100 according to an example of a vapor phase deposition apparatus or “device” includes a holder (which may also be referred to herein as a susceptor) 110 as to an example of a support table, a chamber 120, a shower head 130, a vacuum pump 140, a pressure control valve 142, an out-heater 150, an in-heater 160 and a rotating member 170. A passage 122 which supplies a gas and a passage 124 which discharges the gas are connected to the chamber 120. The passage 122 is connected to the shower head 130. In FIG. 1, necessary structures for explaining the first embodiment are illustrated. The epitaxial deposition apparatus 100 may be provided with portions other than structures in FIG. 1. Moreover, a contraction scale or the like is not coincident with a real object (This applies to other drawings also).

The holder 110 is formed to have an outer periphery taking a circular shape, and is provided with an opening portion to penetrate in a predetermined inside diameter. The holder 110 supports a silicon wafer 101 according to an example of a substrate in contact with a back face of the silicon wafer 101 over a surface depressed to have a predetermined depth from an upper surface side. A plurality of first convex or projecting portions 112 for constraining a substantially horizontal movement in a direction substantially parallel to a plane of the silicon wafer 101 is formed for the silicon wafer 101. The first projecting portion 112 is formed to be extended like a projection toward the center of the holder 110 from a surface to be a base.

The holder 110 is disposed on the rotating member 170 to be rotated around a centerline of the silicon wafer 101 plane which is orthogonal to the silicon wafer 101 plane by means of a rotating mechanism which is not shown. The holder 110 is rotated together with the rotating member 170 so that the silicon wafer 101 can be rotated.

The out-heater 150 and the in-heater 160 are disposed on the back side of the holder 110. It is possible to heat the outer peripheral portion of the silicon wafer 101 and the holder 110 by means of the out-heater 150. The in-heater 160 is disposed under the out-heater 150 and portions other than the outer peripheral portion of the silicon wafer 101 can be heated by means of the in-heater 160. In addition to the in-heater 160, the out-heater 150 is provided for heating the outer peripheral portion of the silicon wafer 101 from which a heat is easily radiated to the holder 110. By thus constituting a double heater, it is possible to enhance an in-plane uniformity of the silicon wafer 101.

The holder 110, the out-heater 150, the in-heater 160, the shower head 130 and the rotating member 170 are disposed in the chamber 120. The rotating member 170 is extended from the inside of the chamber 120 to the rotating mechanism (not shown) on the outside of the chamber 120. A pipe of the shower head 130 is extended from the inside of the chamber 120 to the outside of the chamber 120.

In a state in which the inside of the chamber 120 to be a reactor is held at an atmospheric pressure or in the vacuum having a predetermined degree of vacuum by means of the vacuum pump 140, the silicon wafer 101 is heated by means of the out-heater 150 and the in-heater 160 and a raw gas to be a silicon source is supplied from the shower head 130 into the chamber 120 while the silicon wafer 101 is rotated at a predetermined rotating speed by the rotation of the holder 110. The thermal decomposition or hydrogen reduction of the raw gas is carried out over the surface of the heated silicon wafer 101 to grow a silicon epitaxial film on the surface of the silicon wafer 101. A pressure in the chamber 120 may be regulated into the atmospheric pressure or the vacuum having a predetermined degree of vacuum by means of the pressure control valve 142. In the case in which the ordinary pressure is used, alternatively, it is also possible to employ a structure in which the vacuum pump 140 or the pressure control valve 142 is not provided. In the shower head 130, the raw gas supplied from the outside of the chamber 120 through the pipe is discharged from a plurality of through holes via a buffer in the shower head 130. Therefore, the raw gas can be uniformly supplied onto the silicon wafer 101. By setting the pressures of the holder 110 and the rotating member 170 to be equal to each other on the inside and the outside (setting a pressure in an atmosphere on the surface side of the silicon wafer 101 and a pressure in an atmosphere on the back side thereof to be equal to each other), it is possible to prevent the raw gas from going around the inside of the rotating member 170 or the inside of the rotating mechanism. Similarly, it is possible to prevent a purge gas on the rotating mechanism side (not shown) or the like from leaking into the chamber (the atmosphere on the surface side of the silicon wafer 101).

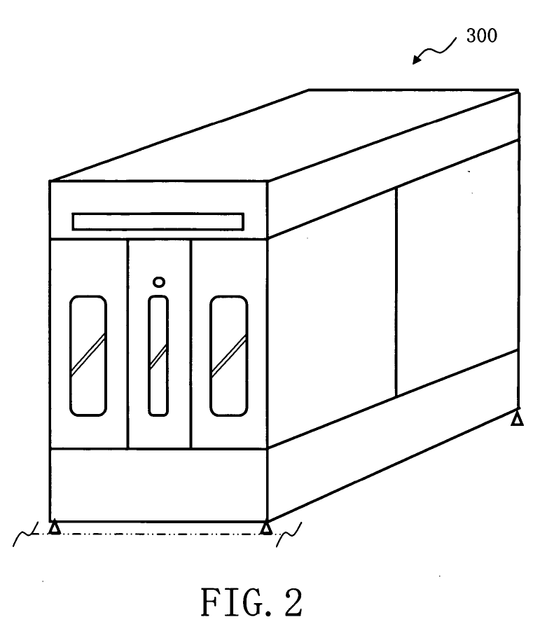

FIG. 2 is a view showing an example of an appearance of the epitaxial deposition apparatus system.

As shown in FIG. 2, an epitaxial deposition apparatus system 300 is wholly surrounded by a housing.

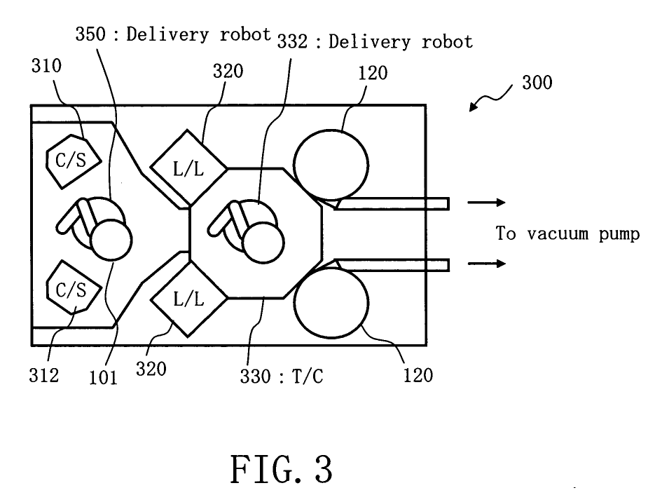

FIG. 3 is a view showing an example of a unit structure of the epitaxial growth apparatus system.

In the epitaxial growth apparatus system 300, the silicon wafer 101 set into a cassette disposed in a cassette stage (C/S) 310 or a cassette stage (C/S) 312 is delivered into a load lock (L/L) chamber 320 by means of a transfer robot 350. Then, the silicon wafer 101 is delivered from the L/L chamber 320 into a transfer chamber 330 by means of a delivery robot 332 disposed in the transfer chamber 330. The delivered silicon wafer 101 is delivered into the chamber 120 of the epitaxial growth apparatus 100 and a silicon epitaxial film is formed on the surface of the silicon wafer 101 by an epitaxial growth method. The silicon wafer 101 on which the silicon epitaxial film is formed is delivered again from the epitaxial growth apparatus 100 into the transfer chamber 330 by means of the delivery robot 332. The delivered silicon wafer 101 is delivered to the L/L chamber 320 and is then returned from the L/L chamber 320 to the cassette disposed in the cassette stage (C/S) 310 or the cassette stage (C/S) 312 by means of the delivery robot 350. In the epitaxial deposition apparatus system 300 shown in FIG. 3, two chambers 120 and two L/L chambers 320 in the epitaxial deposition apparatus 100 are mounted so that a throughput can be enhanced.

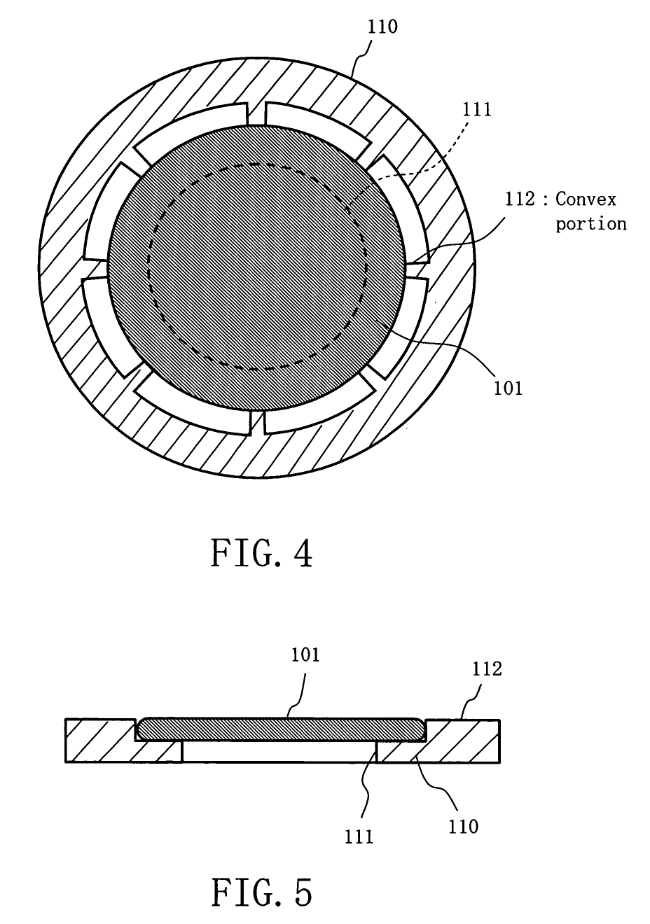

FIG. 4 is a top view showing an example of a state in which the silicon wafer is supported on the holder.

FIG. 5 is a sectional view showing a section of the state in which the silicon wafer is supported on the holder illustrated in FIG. 4.

The first projecting portion 112 formed on the holder 110 projects from a side surface to be connected to a surface with which the back face of the silicon wafer 101 comes in contact toward the center of the holder 110, and a tip thereof is formed to be a plane. Additionally, an inner peripheral portion 111 extends beneath the back face of the wafer 101 to support the wafer 101. Herein, eight projecting portions 112 are disposed uniformly. Even if the holder 110 is rotated and the silicon wafer 101 is moved in a substantially horizontal direction parallel to the silicon wafer plane by a centrifugal force thereof, a part of the side surface of the silicon wafer 101 simply comes in contact with some of the eight projecting portions 112. As a result, such substantially horizontal movement of the silicon wafer 101 is constrained within an area surrounded by the eight projecting portions 112. As compared with the case in which the first projecting portion 112 is not provided but a contact with a large region on the side surface of the holder 110 is carried out, therefore, a contact area can be reduced more. As a result, even if the silicon epitaxial film grown in the side surface portion of the silicon wafer 101 comes in contact with the film deposited on the tip part of the projecting portion 112, it is possible to reduce the sticking of the silicon wafer 101 to the holder 110 because the contact region is small. Although the eight projecting portions 112 are disposed uniformly, the number of the projecting portions 112 is not limited thereto but may be three or more. If the number of the projecting portions 112 is increased, precision in the centering of the silicon wafer 101 can be enhanced more. On the contrary, if the number of the first projecting portions 112 is reduced, it is possible to decrease the contact region of the silicon epitaxial film grown in the side surface portion of the silicon wafer 101 and the film deposited on the tip part of the first projecting portion 112.

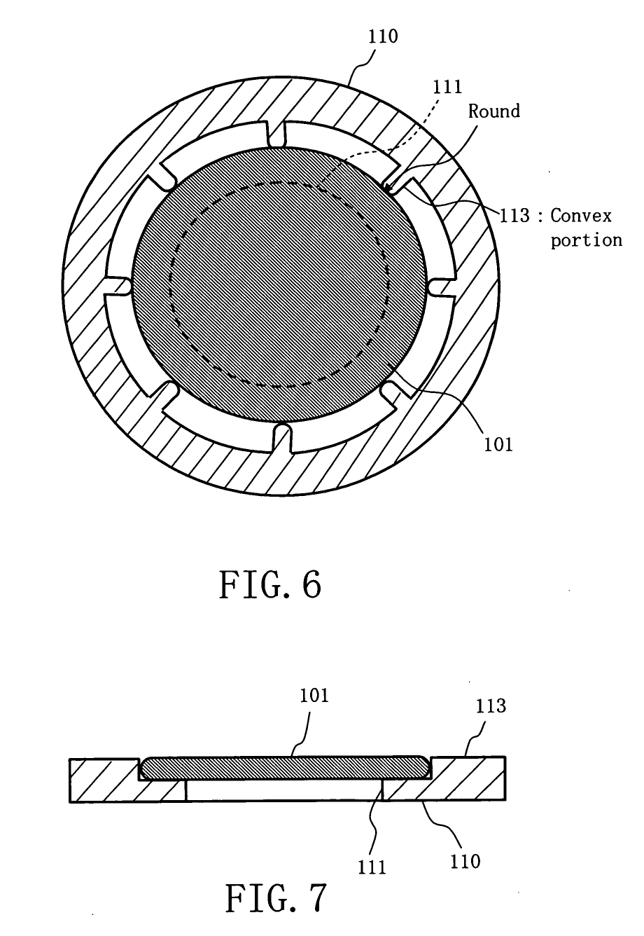

FIG. 6 is a top view showing another example of the state in which the silicon wafer is supported on the holder.

FIG. 7 is a sectional view showing a section of the state in which the silicon wafer is supported on the holder illustrated in FIG. 6.

A projecting portion 113 formed on the holder 110 projects from a side surface to be connected to a surface with which the back face of the silicon wafer 101 comes in contact toward the center of the holder 110, and a tip thereof is formed to be a round curved surface seen from an upper surface. Herein, eight first projecting portions 113 are disposed uniformly. Even if the holder 110 is rotated so that the silicon wafer 101 is moved in a substantially horizontal direction parallel to the silicon wafer surface by a centrifugal force thereof, a part of the side surface of the silicon wafer 101 simply comes in contact with some of the eight projecting portions 113. As a result, such substantially horizontal movement of silicon wafer 101 is constrained with an area surrounded by the eight projecting portions 113. As compared with the case in which the first projecting portion 113 is not provided but a contact is carried out in a large region of the side surface of the holder 110, therefore, a contact area can be reduced more. Furthermore, the tip of the first projecting portion 113 is formed to be a round shaped surface. Also in the case in which a contact with the side surface of the silicon wafer 101 is carried out, therefore, it is possible to make a line contact or a point contact. As a result, even if the silicon epitaxial film grown in the side surface portion of the silicon wafer 101 comes in contact with the film deposited on the tip part of the first projecting portion 113, it is possible to further decrease the contact region. Consequently, it is possible to further reduce the sticking of the silicon wafer 101 to the holder 110. Although the eight projecting portions 113 are disposed uniformly, the number of the projecting portions 113 is not limited thereto but may be three or more. Since this respect is the same as that in the explanation for the number of the first projecting portions 112, description will not be repeated.

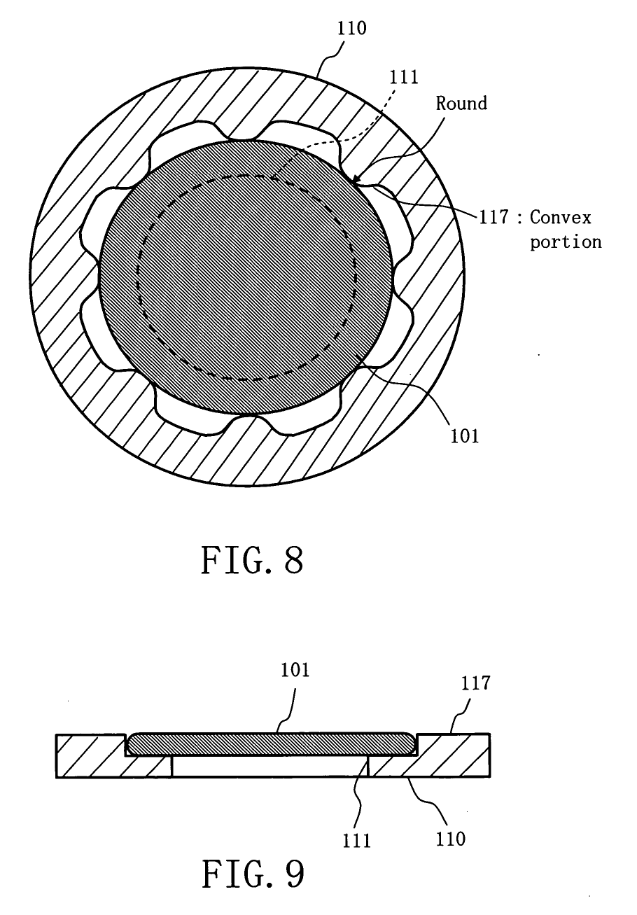

FIG. 8 is a top view showing a further example of the state in which the silicon wafer is supported on the holder.

FIG. 9 is a sectional view showing a section of the state in which the silicon wafer is supported on the holder illustrated in FIG. 8.

A first projecting portion 117 formed on the holder 110 is extended continuously toward the center of the holder 110 so as to be linked through a smooth curved line from a side surface to be connected to a surface with which the back face of the silicon wafer 101 comes in contact, and has a tip formed to be a round shaped surface seen from an upper surface. Since others are the same as in FIGS. 6 and 7, description will not be repeated.

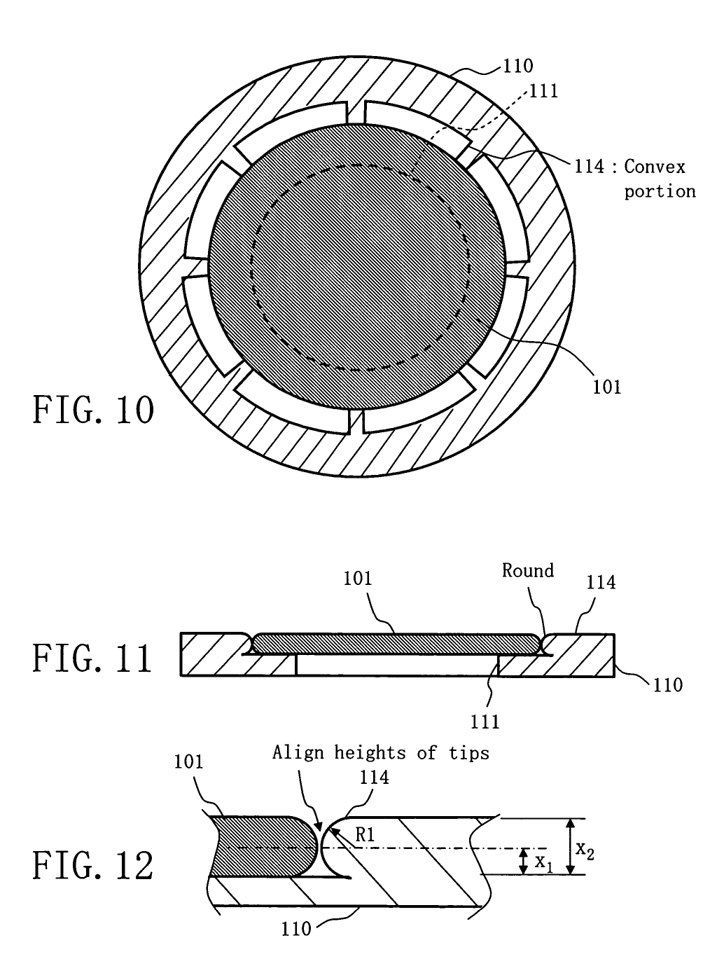

FIG. 10 is a top view showing a further example of the state in which the silicon wafer is supported on the holder.

FIG. 11 is a sectional view showing a section of the state in which the silicon wafer is supported on the holder illustrated in FIG. 10.

A projecting portion 114 formed on the holder 110 projects from a side surface to be connected to a surface with which the back face of the silicon wafer 101 comes in contact toward the center of the holder 110, and a tip thereof is formed to be rounded as seen from a sectional view. In other words, the tip is formed to be a rounded surface projecting from the surface side of the holder 110 toward the back side thereof. Herein, eight projecting portions 114 are disposed uniformly. Even if the holder 110 is rotated so that the silicon wafer 101 is moved in a substantially horizontal direction parallel to the silicon wafer surface by a centrifugal force thereof, a part of the side surface of the silicon wafer 101 simply comes in contact with some of the eight projecting portions 114. As a result, such substantially horizontal movement of the silicon wafer 101 is constrained within an area surrounded by the eight projecting portions 114. As compared with the case in which the first projecting portion 114 is not provided but a contact is carried out in a large region of the side surface of the holder 110, therefore, a contact area can be reduced more. Furthermore, the tip of the first projecting portion 114 is formed to be a round shaped surface. Also in the case in which a contact with the side surface of the silicon wafer 101 is carried out, therefore, it is possible to make a line contact or a point contact. As a result, even if the silicon epitaxial film grown in the side surface portion of the silicon wafer 101 comes in contact with the film deposited on the tip part of the first projecting portion 114, it is possible to further decrease the contact region. Consequently, it is possible to further reduce the sticking of the silicon wafer 101 to the holder 110. Although the eight projecting portions 114 are disposed uniformly, the number of the projecting portions 114 is not limited thereto but may be three or more. Since this respect is the same as that in the explanation for the number of the first projecting portions 112, description will not be repeated.

FIG. 12 is a sectional view showing the outer peripheral portion of the silicon wafer and the convex portion.

As shown in FIG. 12, it is desirable that the projecting portion 114 is formed in such a manner that the tip of the side surface of the silicon wafer 101 is on the level with the tip of the first projecting portion 114. For example, it is desirable that a dimension X, in FIG. 12 is a half of a thickness of the silicon wafer 101. More specifically, in case of a silicon wafer having a diameter of 200 mm, for example, it is desirable that X₁=0.3625 mm is set because the thickness t is 0.725 mm. However, this is not the only case but X₁≈0.3625 mm may be set. In other words, it is desirable that the projecting portion 114 is formed in contact with the silicon wafer 101 in a vertical midpoint area of the side surface of the silicon wafer 101. In other words, it is desirable that the projecting portion 114 is formed in such a manner that the tip part of the convex portion 114 constrains the movement in the substantially horizontal direction as the silicon wafer 101 plane in the vertical midpoint area of the side surface of the silicon wafer 101. Moreover, it is desirable that a dimension X₂ has a value which is equal to or slightly greater than the thickness of the silicon wafer 101. More specifically, for example, in case of a silicon wafer having a diameter of 200 mm, it is desirable that X₂=0.725 to 1.5 mm is set because the thickness t is 0.725 mm. Moreover, it is desirable that a dimension R₁ has a value which is equal to or slightly greater than a half of the thickness of the silicon wafer 101. More specifically, for example, in case of a silicon wafer having a diameter of 200 mm, it is desirable that R₁=0.3625 to 0.75 mm is set because the thickness t is 0.725 mm.

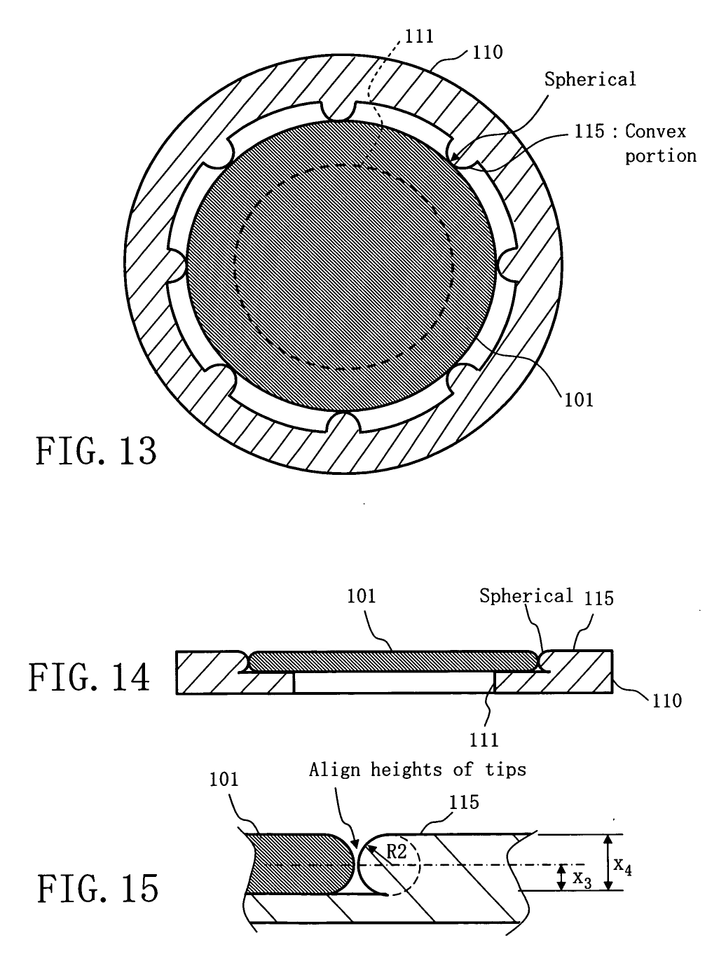

FIG. 13 is a top view showing a further example of the state in which the silicon wafer is supported on the holder.

FIG. 14 is a sectional view showing a section of the state in which the silicon wafer is supported on the holder illustrated in FIG. 13.

A projecting portion 115 formed on the holder 110 projects from a side surface (a first surface) to be connected to a surface (a second surface) with which the back face of the silicon wafer 101 comes in contact toward the center of the holder 110, and a tip thereof is formed to be a spherical curved surface. Herein, eight projecting portions 115 are disposed uniformly. Even if the holder 110 is rotated so that the silicon wafer 101 is moved in a substantially horizontal direction parallel to the silicon wafer surface by a centrifugal force thereof, a part of the side surface of the silicon wafer 101 simply comes in contact with some of the eight first projecting portions 115. As a result, such substantially horizontal movement of the silicon wafer 101 is constrained within an area surrounded by the eight projecting portions 115. As compared with the case in which the first projecting portion 115 is not provided but a contact is carried out in a large region of the side surface of the holder 110, therefore, a contact area can be reduced more greatly. Furthermore, the tip of the first projecting portion 115 is formed to be a spherical curved surface. Also in the case in which a contact with the side surface of the silicon wafer 101 is carried out, therefore, it is possible to make a point contact. As a result, even if the silicon epitaxial film grown in the side surface portion of the silicon wafer 101 comes in contact with the film deposited on the tip part of the first projecting portion 115, it is possible to further decrease the contact region. Consequently, it is possible to further reduce the sticking of the silicon wafer 101 to the holder 110. Although the eight projecting portions 115 are disposed uniformly, the number of the projecting portions 115 is not limited thereto but may be three or more. Since this respect is the same as that in the explanation for the number of the projecting portions 112, description will not be repeated.

FIG. 15 is a sectional view showing the outer peripheral portion of the silicon wafer and the first convex portion.

As shown in FIG. 15, it is desirable that the first projecting portion 115 is formed in such a manner that the tip of the side surface of the silicon wafer 101 is on the level with the tip of the first projecting portion 115. For example, it is desirable that a dimension X₃ in FIG. 15 is a half of a thickness of the silicon wafer 101. More specifically, in case of a silicon wafer having a diameter of 200 mm, for example, it is desirable that X₃=0.3625 mm is set because the thickness t is 0.725 mm. However, this is not the only case but X₁≈0.3625 mm may be set. In other words, it is desirable that the convex portion 115 is formed in contact with the silicon wafer 101 in a vertical midpoint area of the side surface of the silicon wafer 101. In other words, it is desirable that the projecting portion 115 is formed in such a manner that the tip part of the projecting portion 115 constrains the movement in the substantially horizontal direction as the silicon wafer 101 plane in the central part of the side surface of the silicon wafer 101. Moreover, it is desirable that a dimension X₄ has a value which is equal to or slightly greater than the thickness of the silicon wafer 101. More specifically, for example, in case of a silicon wafer having a diameter of 200 mm, it is desirable that X₄=0.725 to 1.5 mm is set because the thickness t is 0.725 mm. In addition, it is desirable that a dimension R₂ has a value which is equal to or slightly greater than a half of the thickness of the silicon wafer 101. More specifically, for example, in case of a silicon wafer having a diameter of 200 mm, it is desirable that R₂=0.3625 to 0.75 mm is set because the thickness t is 0.725 mm.

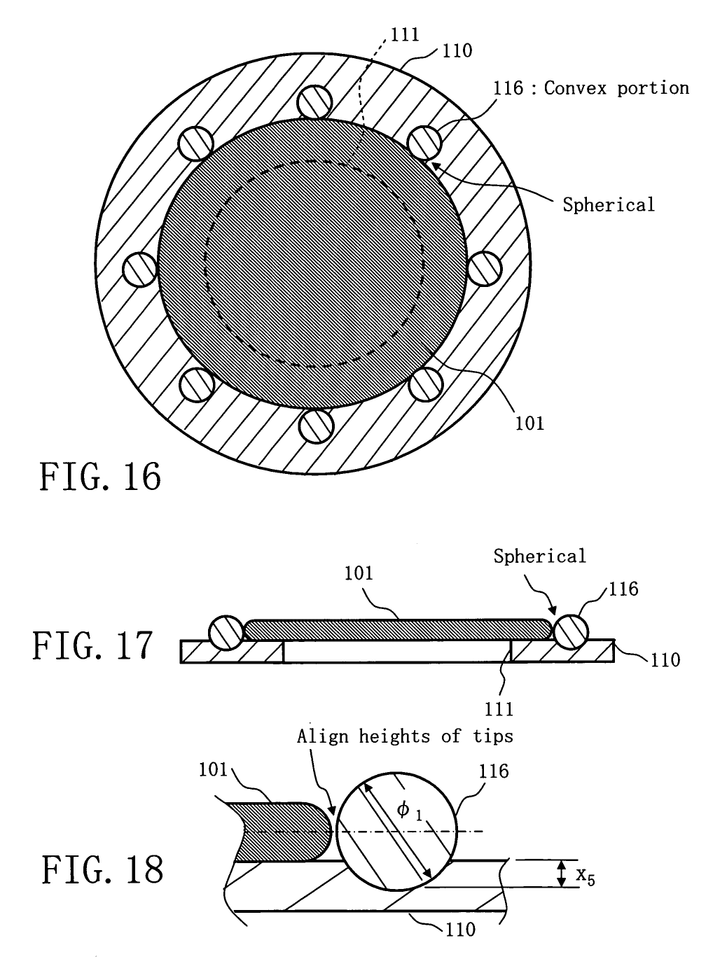

FIG. 16 is a top view showing a further example of the state in which the silicon wafer is supported on the holder.

FIG. 17 is a sectional view showing a section of the state in which the silicon wafer is supported on the holder illustrated in FIG. 16.

A first projecting portion 116 formed on the holder 110 is formed by welding a sphere to a surface with which the back face of the silicon wafer 101 comes in contact. Accordingly, a tip provided toward the side surface of the silicon wafer 101 is formed to be a spherical curved surface. Herein, eight projecting portions 116 are disposed uniformly. Even if the holder 110 is rotated so that the silicon wafer 101 is moved in a substantially horizontal direction parallel to the silicon wafer surface by a centrifugal force thereof, a part of the side surface of the silicon wafer 101 simply comes in contact with some of the eight projecting portions 116. As a result, such substantially horizontal movement of the silicon wafer 101 is constrained within an area surrounded by the eight projecting portions. As compared with the case in which the first projecting portion 116 is not provided but a contact is carried out in a large region of the side surface of the holder 110, therefore, a contact area can be reduced more. Furthermore, the tip of the projecting portion 116 is formed to be a spherical curved surface. Also in the case in which a contact with the side surface of the silicon wafer 101 is carried out, therefore, it is possible to make a point contact. As a result, even if the silicon epitaxial film grown in the side surface portion of the silicon wafer 101 comes in contact with the film deposited on the tip part of the projecting portion 116, it is possible to further decrease the contact region. Consequently, it is possible to further reduce the sticking of the silicon wafer 101 to the holder 110. Although the eight projecting portions 116 are disposed uniformly, the number of the projecting portions 116 is not limited thereto but may be three or more. Since this respect is the same as that in the explanation for the number of the projecting portions 112, description will not be repeated.

FIG. 18 is a sectional view showing the outer peripheral portion of the silicon wafer and the convex portion.

As shown in FIG. 18, it is desirable that the projecting portion 116 is formed in such a manner that the tip of the side surface of the silicon wafer 101 is on the level with the tip of the first convex portion 116. For example, it is desirable that a dimension Φ₁ in FIG. 18 has a slightly greater value than the thickness of the silicon wafer 101 corresponding to an embedment. More specifically, in case of a silicon wafer having a diameter of 20 mm, for example, it is desirable that Φ₁=1 to 1.5 mm is set because the thickness t is 0.725 mm. Moreover, it is sufficient that a dimension X₅ is determined for such an embedment as to position the spherical projecting portion 116. More specifically, it is desirable that X₅=0.1375 to 0.6375 mm is set.

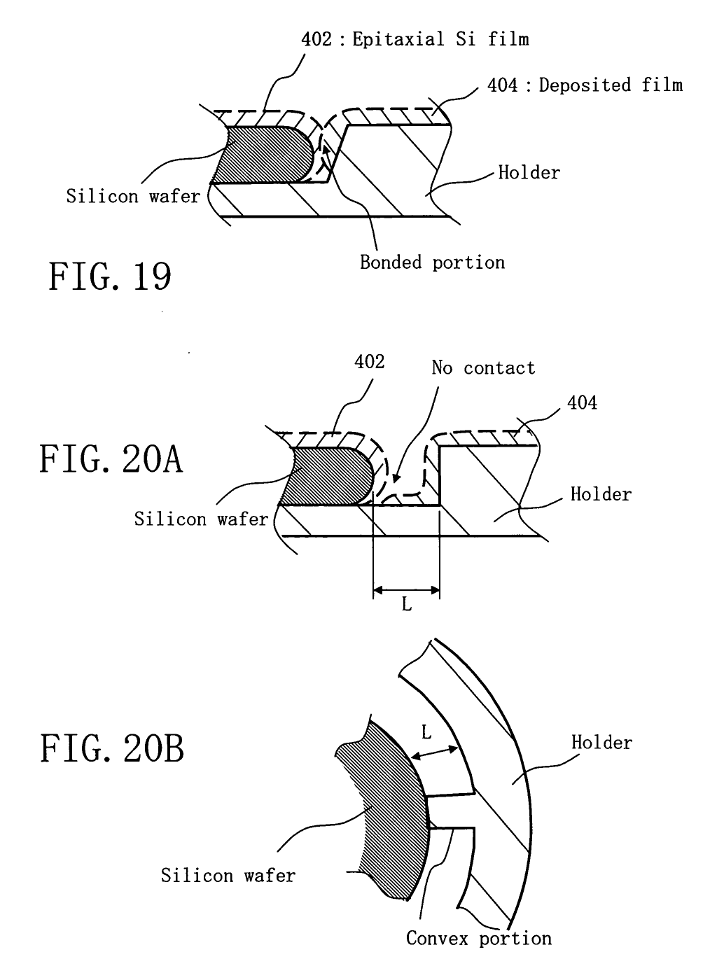

FIG. 19 is a view for explaining a state brought after the formation of a film in the case in which a holder having no first projecting portion formed thereon is used.

FIGS. 20A and 20B are views for explaining a state brought after the formation of a film in the case in which a holder having the first projecting portion formed thereon is used according to the present embodiment.

In the case in which the holder having no first projecting portion formed thereon is used as shown in FIG. 19, a silicon epitaxial film 402 grown in the side surface portion of a silicon wafer comes in contact with a deposited film 404 deposited on the side surface of a counterbore of the holder and they are stuck (bonded) to each other so that the silicon wafer adheres to the holder. On the other hand, in the case in which the holder having the projecting portion formed thereon according to the present embodiment is used as shown in FIG. 20A, the silicon epitaxial film 402 grown in the side surface portion of the silicon wafer can be prevented from coming in contact with the deposited film 404 which is deposited on a bottom face and a side surface of the holder in positions other than the projecting portion. As shown in FIG. 20B, it is desirable that a length L in a direction of a center of the projecting portion projecting toward the direction of a center of the silicon wafer is set to be a double or more of a thickness of a film formed on a surface of the silicon wafer by a raw gas. In the positions other than the projecting portion, a thickness of a film grown on the side surface of the silicon wafer is almost equal to that of a film grown on the silicon wafer side in the portions other than the projecting portion. By setting the length L in the direction of the center of the projecting portion to be a double or more of the thickness of the film to be formed, accordingly, it is possible to avoid the contact of the silicon epitaxial film 402 grown on the side surface of the silicon wafer with the deposited film 404 grown on the silicon wafer side from side surface portions other than the convex portion in the positions other than the projecting portion. For example, in the case in which the silicon epitaxial film is formed in a thickness of 120 μm, it is desirable that the dimension L is set to be equal to or greater than 240 μm, that is, 0.24 mm.

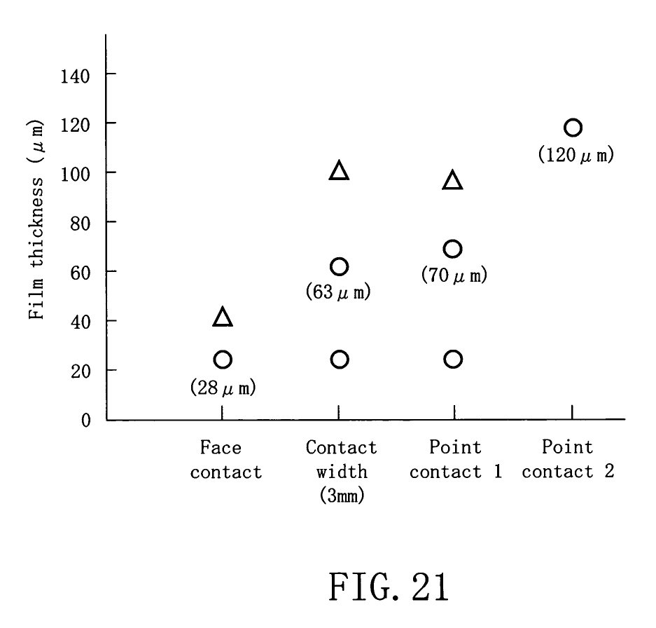

FIG. 21 is a chart showing an example of a relationship between a thickness of a silicon epitaxial film in each holder shape and a condition of sticking to a holder.

34 Pa·m³/s (20 SLM) of a gas obtained by diluting trichlorosilane (SiHCl₃) with hydrogen (H₂) into 25% and 85 Pa·m³/s (50 SLM) of H₂ were supplied respectively as a silicon source and a carrier gas from the shower head 130. More specifically, a concentration of SiHCl₃ in the whole gas was set to be 7.2%. Then, the in-heater 160 was set to be 1100° C. and the out-heater 150 was set to be 1098° C. Moreover, a rotating speed of the silicon wafer was set to be 500 min⁻¹ (500 rpm). An in-chamber pressure was set to be 9.3×10⁴ Pa (700 Torr).

In the case in which the holder in which the first projecting portion is not provided and the projecting portion is not formed according to the present embodiment was used (in case of the simple counterbore) as shown in FIG. 21, the silicon wafer was not stuck to the holder when a silicon epitaxial film was formed in a thickness of 28 μm and the silicon wafer and the holder were slightly stuck to each other when the film was formed in a thickness of 40 μm. On the other hand, in the case in which a projecting portion having a planar tip according to the present embodiment (a contact width of 3 mm with the silicon wafer) was provided, the silicon wafer was not stuck to the holder when the silicon epitaxial film was formed in a thickness of 63 μm and the silicon wafer and the holder were slightly stuck to each other when the film was formed in a thickness of 100 μm. In the case in which a projecting portion having a round or spherical tip according to the present embodiment (a point contact with the silicon wafer) was provided (a point contact 1), furthermore, the silicon wafer was not stuck to the holder when the silicon epitaxial film was formed in a thickness of 70 μm and the silicon wafer and the holder were slightly stuck to each other when the film was formed in a thickness of 90 μm.

As described above, the first projecting portion according to the present embodiment is provided so that it is possible to increase an allowable film thickness more greatly as compared with the case in which the projecting portion is not provided. Also in the case in which the projecting portion is provided, furthermore, it is possible to increase the allowable film thickness more greatly by making the point contact in place of a face contact.

By changing process conditions, that is, decreasing the concentration of the trichlorosilane (SiHCl₃) to be the silicon source and increasing the temperature of the silicon wafer, furthermore, it is possible to increase the allowable film thickness still more. More specifically, the amount of H₂ was increased to be 85 Pa·m³/s (50 SLM) and the concentration of the SiHCl₃ in the whole gas was decreased from 7.2% to 4.2%. Then, the temperature of the in-heater 160 was raised to be 1200° C. and the temperature of the out-heater 150 was raised to be 1126° C. In the case in which the process conditions were changed and the projecting portion having the round or spherical tip according to the present embodiment (a point contact with the silicon wafer) was provided (a point contact 2), the silicon wafer was not stuck to the holder even if the silicon epitaxial film was formed in a thickness of 120 μm.

### Second Embodiment

While the first projecting portion is provided to reduce the contact region of the film grown in the side surface portion of the substrate and the film deposited on the holder side in the first embodiment, description will be given to the shape of the holder in which advantages are poor but the contact region is reduced more greatly than that in the conventional art in a second embodiment.

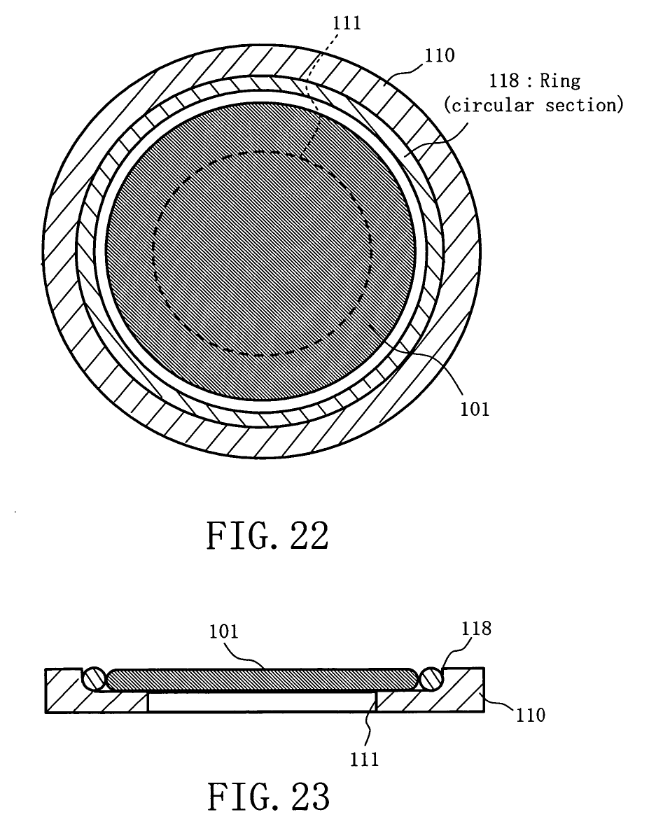

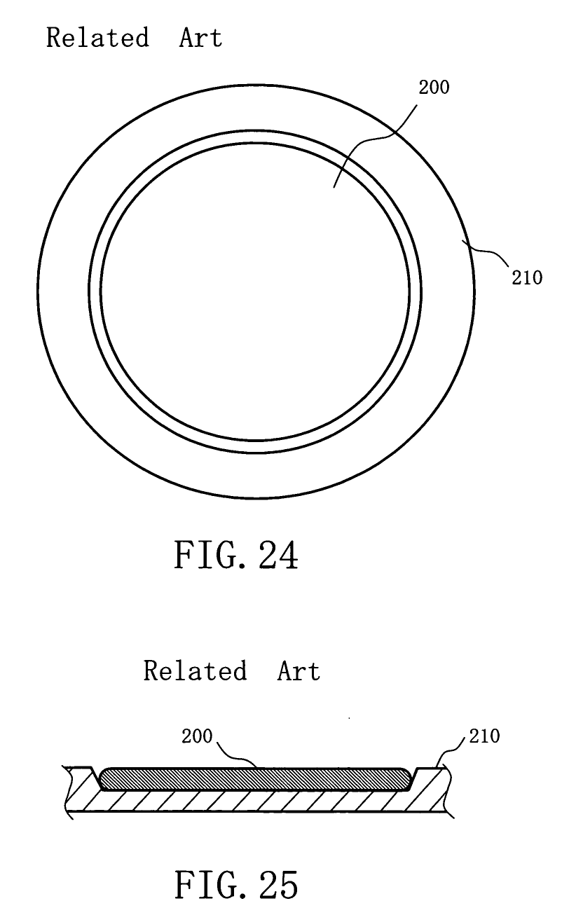

FIG. 22 is a top view showing an example of a state in which a silicon wafer is supported on a holder according to the second embodiment.

FIG. 23 is a sectional view showing a section of the state in which the silicon wafer is supported on the holder illustrated in FIG. 22.

A counterbore or depressed portion having a diameter larger than a diameter of a silicon wafer 101 is formed on a holder 110, and a ring 118 having a circular section is disposed in the counterbore. In other words, the holder 110 includes the ring 118 in which a surface to constrain a movement in the same direction as the silicon wafer 101 plane with respect to the silicon wafer 101 is formed to have a round shaped edge surface projecting toward the silicon wafer 101 side. The silicon wafer 101 is disposed on the inside of the ring 118. The holder 110 and the ring 118 may be welded to each other. By such a structure, a tip (an inner peripheral side) provided toward the side surface of the silicon wafer 101 is formed to be a round shaped edge surface. In other words, the inner peripheral side of the section of the ring 118 is formed to be a round shaped line. Also in the case in which the holder 110 is rotated and the silicon wafer 101 is moved in a substantially horizontal direction parallel to the silicon wafer plane to approach in a certain direction by a centrifugal force thereof, accordingly, a part of the side surface of the silicon wafer 101 can be caused to make a line contact with the round shaped edge part of the ring 118. As a result, such substantially horizontal movement of the silicon wafer 101 is constrained with an area surrounded by the ring 118. As compared with the case in which neither the projecting portion nor the ring 118 is provided and a contact is carried out in a large region on the side surface of the holder 10, therefore, a contact area can be reduced more. As a result, even if a silicon epitaxial film grown in the side surface portion of the silicon wafer 101 comes in contact with a film deposited on the round shaped edge part of the ring 118, it is possible to reduce the sticking of the silicon wafer 101 to the holder 110 more greatly than that in the conventional art because the contact region is small.

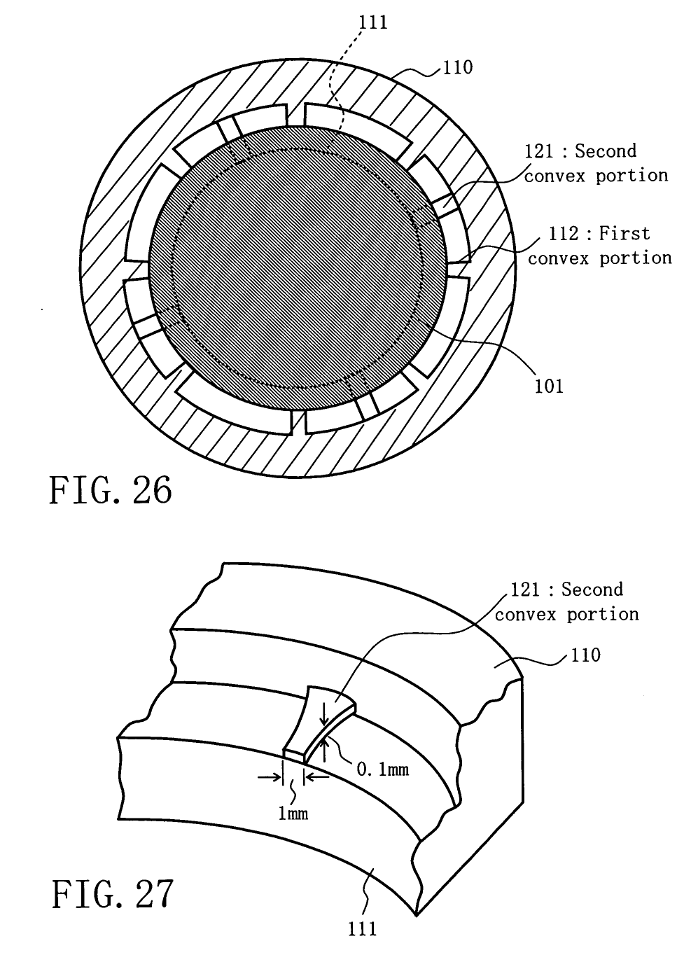

FIG. 26 is a top view showing an example of a state in which the silicon wafer 101 is supported on a holder (support table) 110, illustrating an example in which a plurality of first projecting portions 112 and a plurality of second projecting portions 121 are provided individually. In this example, eight first projecting portions and four second projecting portions are provided. If eight projecting portions are provided, it is desirable that the number of the second projecting portions is also eight. It is sufficient that the number is three to ten.

FIG. 27 is a perspective view showing a part of the second projecting portion 121 which is partially enlarged. The second projecting portion 121 according the present embodiment has a thickness of 0.1 mm and a width of 1 mm, and a size which depends on the silicon epitaxial film to be grown, and furthermore, depends on a size of the silicon wafer 101.

While a top face of the second projecting portion may have an arcuate or spherical shape or include multiple projections, furthermore, it is desirable that the contact area with the silicon wafer 101 is smaller.

Since the second projecting portion is thus provided, the sticking to the support table on the back face of a substrate is rarely observed so that it is possible to perform an epitaxial growth in a thickness of approximately 30 μm which buries a trench for an isolation of an IGBT, for example, and furthermore, an epitaxial growth in 50 μm or more to be a thickness of an n-base of the IGBT. In order to increase a breakdown voltage in a power MOS, moreover, it is also possible to use a trench for burying a p-type semiconductor layer in a thickness of 30 μm or more.

More specifically, the projecting portion 112 formed on the holder 110 is extended from a side surface to be connected to a surface (a second convex portion) with which the back face of the silicon wafer 101 comes in contact projecting toward a center of the holder 110, and a tip thereof is formed to be a plane. Herein, eight projecting portions 112 are disposed uniformly. Even if the holder 110 is rotated and the silicon wafer 101 is moved in a substantially horizontal direction parallel to the silicon wafer plane by a centrifugal force thereof, a part of the side surface of the silicon wafer 101 comes in contact with some of the eight projecting portions 112. As a result, such substantially horizontal movement of the silicon wafer 101 is constrained within the area surrounded by the eight projecting portions 112. As compared with the case in which the projecting portion 112 is not provided but a contact with a large region on the side surface of the holder 110 is made, therefore, a contact area can be reduced more.

As a result, even if the silicon epitaxial film grown in the side surface portion of the silicon wafer 101 comes in contact with the film deposited on the tip part of the projecting portion 112, it is possible to reduce the sticking of the silicon wafer 101 to the holder 110 because the contact region is small.

Although the eight projecting portions 112 are disposed uniformly, the number of the projecting portions 112 is not limited thereto but may be three or more. If the number of the projecting portions 112 is increased, precision in the centering of the silicon wafer 101 can be enhanced more. To the contrary, if the number of the projecting portions 112 is reduced, it is possible to decrease the contact region of the silicon epitaxial film grown in the side surface portion of the silicon wafer 101 and the film deposited on the tip part of the projecting portion 112.

Furthermore, a plurality of (four in the present embodiment) second projecting portions 121 is provided on the surface to come in contact with the silicon wafer 101, and the silicon wafer 101 is supported on top faces of the second projecting portions 121.

In addition to the first projecting portion, thus, the second projecting portion is provided. Consequently, the sticking to the support table on the back face of the silicon wafer 101 is rarely observed so that an epitaxial growth in a thickness of 60 μm or more to be the thickness of the n-base can also be performed.

As a matter of course, in addition to the IGBT, the present invention can be applied to the formation of a thick base epitaxial layer of a power MOS to be a power semiconductor which requires a high breakdown voltage, and furthermore, a GTO (Gate Turn-Off thyristor) and a general thyristor (SCR) which are used as switching units for a train or the like.

As described above, in a vapor phase deposition apparatus according to an aspect of the present invention in which a substrate mounted on a support table is accommodated in a chamber, and a first passage which supplies a gas to form a film and a second passage which discharges the gas are connected to the chamber, the support table is provided with a plurality of first projecting portions to constrain a movement in the same direction as a substrate surface with respect to the substrate, and the substrate is supported on a surface to come in contact with a back face of the substrate.

By such a structure, also in the case in which the substrate is moved in the same direction as the substrate surface to approach in a certain direction, any of the first projecting portions comes in contact with a side surface of the substrate. Even if the film grown in the side surface portion of the substrate comes in contact with the film deposited on the tip part of the projecting portion, therefore, a contact region can be reduced.

Furthermore, it is desirable that the projecting portion has a tip part formed to take a round shape.

By forming the tip part to take the round shape, it is possible to cause a contact with the side surface of the substrate to be a point contact or a line contact. As a result, the contact region can be reduced.

Alternatively, the projecting portion has the tip part formed to take a spherical shape.

By forming the tip part to take the spherical shape, it is possible to cause the contact with the side surface of the substrate to be the point contact. As a result, the contact region can be further reduced.

Furthermore, the first projecting portion projects in a direction toward a center of the substrate and a length in a direction of a center of the first projecting portion is twice or more of a thickness of a film to be formed on a surface of the substrate with a predetermined gas.

In positions other than the first projecting portion, a film grown on the side surface of the substrate and a film grown on the substrate side other than the projecting portion have thicknesses which are almost equal to each other. By setting the length in the direction of the center of the projecting portion to be twice or more of the thickness of the film formed on the surface of the substrate with the predetermined gas, accordingly, it is possible to avoid a contact of the film grown on the side surface of the substrate and the film grown on the substrate side in the portions other than the first projecting portion in the positions other than the first projecting portion.

As described above, in a vapor phase deposition apparatus according to another aspect of the present invention in which a substrate mounted on a support table is accommodated in a chamber, and a first passage which supplies a gas to form a film and a second passage which discharges the gas are connected to the chamber, the support table has a surface to constrain a movement in the same direction as a substrate surface with respect to the substrate which is formed to have a round shape projecting toward the substrate side, and supports the substrate on a surface to come in contact with a back face of the substrate.

The surface to constrain the movement in the same direction as the substrate surface with respect to the substrate is formed to have the round shape projecting toward the substrate side. Also in the case in which the substrate is moved in the same direction as the substrate surface to approach in a certain direction, therefore, a portion to come in contact with a side surface of the substrate is a tip part of a round shaped edge. Even if a film grown in the side surface portion of the substrate and a film deposited on the round shape come in contact with each other, therefore, a contact region can be reduced.

In a vapor phase deposition apparatus according to a further aspect of the present invention, furthermore, it is suitable to add a reduction in a concentration of a gas and an increase in a temperature of the substrate to conditions in addition to the features described above. By such a structure, it is possible to further reduce the sticking of the substrate to the support portion.

As described above, in a vapor phase deposition apparatus according to a further aspect of the present invention in which a substrate mounted on a support table is accommodated in a chamber, and a first passage which supplies a gas to form a film and a second passage which discharges the gas are connected to the chamber, the support table has a plurality of second projecting portions on a surface to come in contact with the substrate and the substrate is supported on top faces of the second projecting portions.

Thus, the sticking to the support table on the back face of the substrate is rarely observed so that an expitaxial growth in a thickness of 50 μm or more can also be performed.

It is desirable that the number of the second projecting portions is three to ten. If the number is larger than ten, the contact area on the back face of the substrate is increased so that a difference from that in the conventional art is almost eliminated. If the number is smaller than three, moreover, the substrate itself becomes unstable, which is not preferable for the epitaxial growth.

It is desirable that the second convex portion has a height of 0.1 mm to 0.5 mm and a width of 0.5 mm to 3 mm. In some cases, the values are varied depending on a film forming apparatus.

Moreover, the top face of the second projecting portion may take a flat shape, an arcuate or spherical shape or include multiple projections, and it is desirable that the contact face is as small as possible.

As described above, in a vapor phase deposition apparatus according to a further aspect of the present invention in which a substrate mounted on a support table is accommodated in a chamber, and a first passage which supplies a gas to form a film and a second passage which discharges the gas are connected to the chamber, the support table is provided with a plurality of first projecting portions to constrain a movement in the same direction as a substrate surface with respect to the substrate and a plurality of second projecting portions on a face to come in contact with the substrate, and the substrate is supported on top faces of the second projecting portions. By such a structure, the sticking to the support table on the side surface and back face of the substrate is rarely observed so that an expitaxial growth in a thickness of 60 μm or more can also be performed.

As described above, according to the embodiments, even if the film grown in the side surface portion of the substrate and the film deposited on the tip part of the projecting portion come in contact with each other, the contact region can be decreased. Therefore, it is possible to reduce the sticking of the substrate to the support portion. Even if the film grown in the side surface portion of the substrate and the film deposited on the tip of the round surface come in contact with each other, alternatively, the contact region can be decreased. Therefore, it is possible to reduce the sticking of the substrate to the support portion. Furthermore, the sticking to the support table in the back face of the substrate is almost eliminated so that an epitaxial growth in a thickness of 50 μm or more can also be carried out.

The description has been given to the embodiments with reference to the specific examples. However, the present invention is not restricted to these specific examples. For example, while the description has been given to the epitaxial deposition apparatus as an example of the vapor phase deposition apparatus, this is not the only case but it is also possible to use any apparatus for causing a predetermined film to be vapor phase grown on a sample face. For example, it is also possible to use a apparatus for growing a polysilicon film.

While the portions which are not directly required for the description of the present invention, for example, a structure of the apparatus, a control technique and the like have been omitted, moreover, it is possible to properly select and use the structure of the apparatus and the control technique which are required. For example, although the structure of the control portion for controlling the epitaxial deposition apparatus 100 has not been described, it is apparent that the structure of the control portion to be required is properly selected and used.

All vapor phase deposition apparatuses which comprise the elements according to the present invention and can be properly designed and changed by the skilled in the art and the shape of the support member are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table includes a plurality of projecting portions to constrain substantially horizontal movement of the substrate within an area surrounded by the plurality of projecting portions, and a bottom face of the support table for supporting a back face of the substrate.

2. The vapor phase deposition apparatus according to claim 1, wherein each of the projecting portions has a round shaped tip part.

3. The vapor phase deposition apparatus according to claim 1, wherein each of the projecting portions has a spherical tip part.

4. The vapor phase deposition apparatus according to claim 1, wherein the substrate is a wafer, and
the projecting portions are extended in a direction toward a center of the area surrounded by the projecting portions, and a length of each of the projecting portions in the direction toward the center of the area surrounded by the projecting portions is double or more of a thickness of a film to be formed on the wafer with the gas.

5. The vapor phase deposition apparatus according to claim 1, wherein each of the projecting portions has a tip part which is adapted to constrain substantially horizontal movement of the substrate within the area surrounded by the projecting portions.

6. The vapor phase deposition apparatus according to claim 1, wherein the substrate is a wafer, and
the projecting portions are formed to come in contact with a vertical midpoint area of a side surface of the wafer.

7. The vapor phase deposition apparatus according to claim 1, wherein the substrate is a wafer, and
the projecting portions are formed to make a line contact with a side surface of the wafer.

8. The vapor phase deposition apparatus according to claim 1, wherein the substrate is a wafer, and
the projecting portions are formed to make a point contact with a side surface of the wafer.

9. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table is provided with a ring adapted to constrain substantially horizontal movement of the substrate within an area surrounded by the ring.

10. The vapor phase deposition apparatus according to claim 9, wherein the substrate is a wafer, and
the ring has a round shaped edge adapted to make a contact with a side surface of the wafer.

11. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table includes a first surface adapted to constrain substantially horizontal movement of the substrate, the first surface being formed to be round and projecting toward the substrate, and a second surface of the support table for supporting a back face of the substrate.

12. The vapor phase deposition apparatus according to claim 11, wherein the substrate is a wafer, and
the first surface is formed to constrain the substantially horizontal movement of the wafer by making a contact with a side surface of the wafer.

13. The vapor phase deposition apparatus according to claim 11, wherein the substrate is a wafer, and
the first surface is formed to come in contact with a vertical midpoint area of a side surface of the wafer.

14. The vapor phase deposition apparatus according to claim 11, wherein the substrate is a wafer, and
the first surface is formed to make a line contact with a side surface of the wafer.

15. The vapor phase deposition apparatus according to claim 11, wherein the substrate is a wafer, and
the first surface is formed to make a point contact with a side surface of the wafer.

16. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table includes a plurality of projecting portions each including a top face, selected ones of the top faces of the projecting portions for contacting and supporting the substrate.

17. The vapor phase deposition apparatus according to claim 16, wherein the number of the projecting portions is three to ten.

18. The vapor phase deposition apparatus according to claim 16, wherein each of the projecting portions has a height of 0.1 mm to 0.5 mm and a width of 0.5 mm to 3 mm.

19. The vapor phase deposition apparatus according to claim 16, wherein the top face of each of the projecting portions has one of a flat shape and an arcuate shape, or includes multiple projections.

20. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table includes a plurality of first projecting portions to constrain substantially horizontal movement of the substrate within an area surrounded by the first projecting portions, and a plurality of second projecting portions having top faces adapted to support the substrate thereon.

21. A vapor phase deposition method using a vapor phase deposition apparatus in which a substrate mounted on a support table is accommodated in a chamber, and a first passage which supplies a gas to form a film and a second passage which discharges the gas are connected to the chamber, the method comprising:
rotating the support table including a plurality of projecting portions and constraining substantially horizontal movement of the substrate within an area surrounded by the plurality of projecting portions, while supporting a back face of the substrate with a bottom face portion of the support table; and
supplying the gas which forms a film from the first passage to carry out an epitaxial growth.

22. A vapor phase deposition method using a vapor phase deposition apparatus in which a substrate mounted on a support table is accommodated in a chamber, and a first passage which supplies a gas to form a film and a second passage which discharges the gas are connected to the chamber, the method comprising:
rotating the support table including a ring and constraining substantially horizontal movement of the substrate within an area surrounded by the ring, while supporting a back face of the substrate with a bottom face portion of the support table; and
supplying the gas which forms a film from the first passage to carry out an epitaxial growth.

23. A vapor phase deposition method using a vapor phase deposition apparatus in which a substrate mounted on a support table is accommodated in a chamber, and a first passage which supplies a gas to form a film and a second passage which discharges the gas are connected to the chamber, the method comprising:
rotating the support table including a first surface, which is formed to be round and projecting toward the substrate and constraining substantially horizontal movement of the substrate, while supporting a back face of the substrate with a second surface of the support table; and
supplying the gas which forms a film from the first passage to carry out an epitaxial growth.

24. A vapor phase deposition method using a vapor phase deposition apparatus in which a substrate mounted on a support table is accommodated in a chamber, and a first passage which supplies a gas to form a film and a second passage which discharges the gas are connected to the chamber, the method comprising:
rotating the support table including a plurality of first projecting portions and constraining substantially horizontal movement of the substrate within an area surrounded by the plurality of first projecting portions, and a plurality of second projecting portions adapted to come in contact with the substrate, while supporting the substrate on top faces of the second projecting portions; and
supplying the gas which forms a film from the first passage to carry out an epitaxial growth.

25. A support table adapted to be accommodated in a chamber of a vapor phase deposition apparatus to support a substrate on which a film is to be formed with gas that is supplied to the chamber, the support table comprising:
a holder; and
a plurality of projecting portions formed on the holder, the plurality of projecting portions defining an area surrounded by the plurality of projecting portions,
a surface of the holder being adapted to support a back face of the substrate, and substantially horizontal movement of a substrate being adapted to be constrained in the area surrounded by the plurality of projecting portions.
